(19) United States
(12) Patent Application Publication
(10) Pub. No.: US 2026/0323178 A1
(43) Pub. Date: Oct. 15, 2026

(54) COLUMN MEMORY CIRCUIT, CHIP, IMAGE SENSOR AND IMAGING DEVICE

(71) Applicant: MAGVISION SEMICONDUCTOR (BEIJING) INC, Daxing District (CN)

(72) Inventors: Kaiyuan WU, Daxing District (CN); Yi LIU, Daxing District (CN)

(21) Appl. No.: 19/648,704

(22) Filed: Apr. 15, 2026

(30) Foreign Application Priority Data
Apr. 15, 2025 (CN) 202510473558.X

(51) Int. Cl. H04N 25/616; H04N 25/767; H04N 25/78

(52) U.S. Cl. CPC H04N 25/616; H04N 25/767; H04N 25/78

(57) ABSTRACT

The present invention provides a column memory circuit, chip, image sensor and imaging device. The column memory circuit includes M×N bank modules, N readout modules and a data transmission module. The column memory circuit further includes correlated double sampling modules arranged in the respective readout modules. Each bank module has a first terminal for receiving a first data signal and a second terminal coupled to a first terminal of an associated one of the readout modules. Each readout module has a second terminal coupled to the data transmission module. The bank modules convert the received first data signals into second data signals, and the readout modules are configured for correlated double sampling processing on the second data signals by the correlated double sampling modules, which produces a third data signal output from the data transmission module.

### CROSS-REFERENCE TO RELATED APPLICATION

This application claims the priority of Chinese patent application number 202510473558.X, filed on Apr. 15, 2025, the entire contents of which are incorporated herein by reference.

### TECHNICAL FIELD

The present invention relates to the field of image processing technology and, in particular, to a column memory circuit, chip, image sensor and imaging device.

### BACKGROUND

An image sensor, typically including, amongst others, a pixel array, an analog-to-digital converter (ADC) and a column memory circuit, is a device that converts optical images into electrical signals. For example, reference is made to FIG. 1, a schematic diagram showing data flow in an imaging process. As can be seen from FIG. 1, pixel cells 111 in a pixel array 110 (not shown in FIG. 1; see FIG. 7 described below) are responsible for converting a collected optical image signal into a voltage signal and outputting the voltage signal to an ADC 120. The ADC 120 is responsible for comparing the received voltage signal with a ramp signal and, when the two signals are equal, generating a pulse signal. Upon receiving the pulse signal, a column memory circuit 130 latches counter data, processes the data in a certain manner, and serially outputs it to an image signal processor (ISP) 150. The ISP 150 carries out extraction and optimization processing (e.g., color correction, gamma correction, etc.) on the received image data, producing an image suitable for display, storage and/or further processing. The image is then output to an interface circuit 160.

Studies show that existing column memory circuits are large in area and consume much power. Despite successful use in high-performance image sensors, they are not suitable for use in low-cost image sensors.

It should be noted that the information disclosed in this Background section is merely intended to provide a better understanding of the general context of the present invention and should not be taken as an acknowledgement or any form of admission that the information forms part of the common general knowledge of those skilled in the art.

### SUMMARY

In view of the large area and high power consumption problems with column memory circuits in conventional image sensors, the present invention aims to provide a column memory circuit, chip, image sensor and imaging device. According to the present invention, the column memory circuit has a significantly reduced area and good performance and can significantly reduce the cost of an image sensor employing it.

This object is attained by a column memory circuit for use in an image sensor described herein. The column memory circuit includes M×N bank modules, N readout modules and a data transmission module. The column memory circuit further includes correlated double sampling (CDS) modules arranged in the respective readout modules. Each bank module has a first terminal configured to receive a first data signal. Each bank module has a second terminal coupled to a first terminal of an associated one of the readout modules. Each readout module has a second terminal coupled to the data transmission module. M is greater than or equal to 2 (i.e., M≥2).

The bank modules are configured to convert the received first data signals into second data signals. The readout modules are configured for CDS processing on the second data signals by the CDS modules, which produces a third data signal. The data transmission module is configured to output the third data signal.

Optionally, each CDS module may include a plurality of first transistors.

Optionally, each bank module may include a first latch, a transcoder module and a buffer module, which are connected in sequence, wherein the associated readout module further includes a second latch, a flip-flop and a multiplexer, and the second latch, the respective CDS module, the flip-flop and the multiplexer are connected in sequence,
the first latch configured to, when receiving a first control signal from the image sensor, latch the first data signal and provide the latched first data signal to the transcoder module, the transcoder module configured to transcode the first data signal into a fourth data signal, the buffer module configured to buffer the fourth data signal, obtaining a first set of second data signals for transmission to the second latch and, after the first set of second data signals is obtained, buffer a second set of second data signals for transmission to the CDS module,
the second latch configured to, when receiving a second control signal, latch the first set of second data signals, the CDS module configured to perform CDS processing on the first and second sets of second data signals, producing third data signals, the flip-flop, when receiving a third control signal from the image sensor, passing the third data signals on to the multiplexer, the multiplexer configured to select one of the third data signals according to a fourth control signal from the image sensor and provide it to the data transmission module.

Optionally, the first data signal may be encoded using Gray code, and the fourth data signal may be binary encoded.

Optionally, the flip-flop may include a D-type flip-flop.

Optionally, each bank module may include a first latch and a buffer module, which are connected in sequence, wherein the associated readout module further includes a transcoder module, a second latch, a flip-flop and a multiplexer, and the transcoder module, the second latch, the respective CDS module, the flip-flop and the multiplexer are connected in sequence,
the first latch configured to, when receiving a first control signal from the image sensor, latch the first data signal and provide the latched first data signal to the buffer module, the buffer module configured to buffer the first data signal and thereby obtain second data signals and provide the second data signals to the transcoder module,
the transcoder module configured to transcode the second data signals into a first set of fifth data signals for transmission to the second latch and, after the first set of fifth data signals is obtained, transcode subsequently received second data signals into a second set of fifth data signals for transmission to the CDS module, the second latch configured to, when receiving a second control signal, latch the first set of fifth data signals, the CDS module configured to perform CDS processing on the first and second sets of fifth data signals, producing third data signals, the flip-flop, when receiving a third control signal from the image sensor, passing the third data signals on to the multiplexer, the multiplexer configured to select one of the third data signals according to a fourth control signal from the image sensor and provide it to the data transmission module.

Optionally, the transcoder module may include a plurality of second transistors.

The above object is also attained by a chip for use in an image sensor, on which the column memory circuit as defined above is integrated.

The above object is also attained by an image sensor including the column memory circuit or chip as defined above.

The above object is also attained by an imaging device including the column memory circuit, chip or image sensor as defined above.

Compared to the prior art, the column memory circuit, chip, image sensor and imaging device of the present invention offer the following advantages:

Differing from conventional designs with CDS modules being incorporated in bank modules, the column memory circuit of the present invention incorporates CDS modules in readout modules. This design leverages the fact that the number of readout modules is much less than that of bank modules to significantly reduce the number of CDS modules, resulting in cost savings and reducing the circuit area that they occupy. Accordingly, the footprint of the column memory circuit can be significantly reduced while ensuring its good performance. The cost of an image sensor employing this column memory circuit can be significantly reduced, and the column memory circuit can be suitably used in low-cost image sensors.

Since the chip, image sensor and imaging device are based on the same inventive concept as the column memory circuit, they have at least all the advantages of the column memory circuit. Such advantages have been described in detail above in connection with the column memory circuit and are not repeated herein, and reference is made to the above description for more details.

### BRIEF DESCRIPTION OF THE DRAWINGS

FIG. 1 schematically illustrates data flow in an imaging process.

FIG. 2 schematically illustrates data flow in a column memory circuit of an image sensor.

FIG. 3 schematically illustrates the topology of a column memory circuit in a conventional image sensor.

FIG. 4 shows a schematic block diagram of a column memory circuit embodying the present invention.

FIG. 5 schematically illustrates the topology of a column memory circuit according to a first embodiment of the present invention.

FIG. 6 schematically illustrates the topology of a column memory circuit according to a second embodiment of the present invention.

FIG. 7 shows a schematic block diagram of an imaging device embodying the present invention.

### LIST OF REFERENCE NUMERALS

100 Image Sensor; 110, Pixel Array; 111 Pixel Cell; 120 Adc; 130, 140 Column Memory circuit; 150 ISP; 160 interface circuit;
Bank0, Bank1, Bank2, Bank3, 130A, 141, 141A, 141B bank module; R01, R23, 130B, 142, 142A, 142B, 142C, 142D readout module; 170 data transmission module;
131, 141A1, 141B1 first latch; 132, 141A2, 142B1 transcoder module; 133, 142A1, 142B2 second latch; 134, 143 CDS module; 135, 141A3, 141B2 buffer module; 136, 142A2, 142B3 flip-flop; 137, 142A3, 142B4 multiplexer;
GC Gray code data; CMP comparator data; BLK_EN black-level signal; GBL output signal terminal of adjacent readout module;

D1 first data signal; D2 second data signal; D3 third data signal; D4, fourth data signal; D5 fifth data signal;

T1 first control signal; T2 second control signal; T3 third control signal; T4 fourth control signal; 200 application.

### DETAILED DESCRIPTION

A column memory circuit, chip, image sensor and imaging device proposed herein will be described in greater detail below with reference to the accompanying drawings. From the following description, advantages and features of the present invention will become more apparent. Note that the figures are provided in a very simplified form not necessarily drawn to exact scale for the only purpose of helping to explain the disclosed embodiments in a more convenient and clearer way. In order that the objects, features and advantages of the present invention can be more apparent and readily understood, reference is to be made to the accompanying drawings. It would be recognized that architectural, proportional, dimensional and other details in the figures are presented only for the purpose of facilitating, in conjunction with the disclosure herein, the understanding and reading of those familiar with the art, rather than being intended to limit conditions under which the present invention can be implemented. Therefore, any and all architectural modifications, proportional variations or dimensional changes that achieve the same or similar benefits and objects as the present invention are considered to fall within the scope of the teachings herein. The specific design features of the invention as disclosed herein, including, for example, specific dimensions, orientations, locations and shapes, will be determined in part by the particular intended application and use environment. Additionally, in the embodiments described below, like reference numerals may be sometimes used to refer to the same or functionally similar elements throughout different figures, while description thereof may not be repeated. In this specification, similar reference numerals and letters refer to similar items in the figures, and thus once an item is defined in one figure, it may not be discussed for following figures. Further, if a method is described herein as including a series of steps, the order of these steps as presented herein is not necessarily the only order in which they can be performed, and some of the stated steps may be omitted and/or other steps not described herein may be added to the method.

It is to be noted that relational terms such as “first,” “second,” and the like may be used herein solely to distinguish one entity or action from another entity or action, without necessarily requiring or implying any actual such relationship or order between such entities or actions, or denoting or implying relative importance of them, or implicitly indicating the number of them. Moreover, the terms “comprise”, “include” and any variations thereof are intended to cover a non-exclusive inclusion, such that a process, method, article, or apparatus that includes a list of elements is not necessarily limited to those elements, but may include other elements not expressly listed or inherent to such process, method, article, or apparatus. An element preceded by “comprises . . . a” does not, without more constraints, preclude the existence of additional identical elements in the process, method, article, or apparatus that includes the element. As used herein, the singular forms “a”, “an” and “the” include plural referents, and the term “or” is generally employed in the sense of “and/or”, “a plurality of” of “at least one”, and “at least two” of “two or more”. In addition, the terms “first,” “second,” and “third” are intended only for illustration and are not to be construed as indicating or implying relative importance, or as implicitly indicating the number of the referenced items.

It will be understood that when an element is referred to as being “connected to”, “attached to” or “coupled to” another element, it can be directly connected, attached or coupled to the other element, or intervening elements may also be present. In contrast, when an element is referred to as being “directly connected to” or “directly attached to” another element, there are no intervening elements.

To facilitate understanding and illustration of the present invention, before describing specific embodiments of the proposed column memory circuit, image sensor and imaging device in detail, primary studies on the present invention are first briefed below.

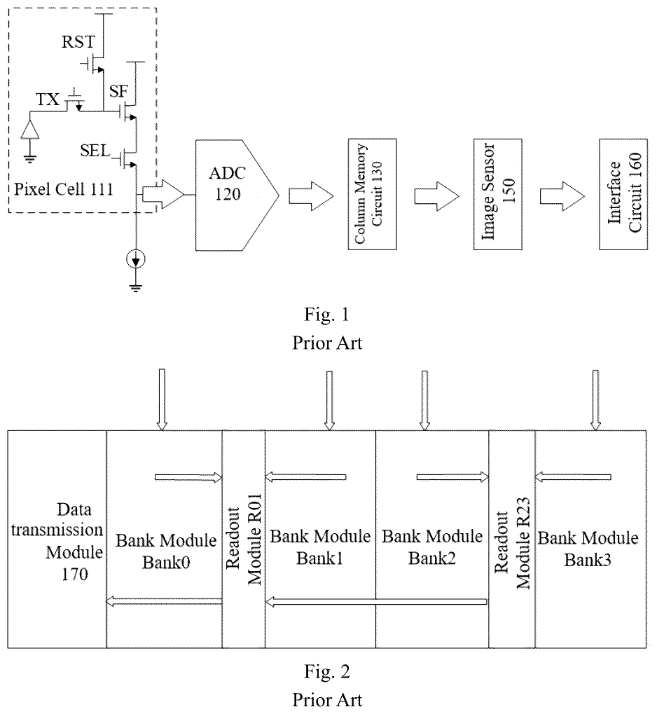

Reference is first made to FIG. 2, which schematically illustrates data flow in a column memory circuit of an image sensor. As shown in FIG. 2, the column memory circuit includes, as an example, four bank modules Bank0, Bank1, Bank2 and Bank3, two readout modules R01 and R23 and a data transmission module 170. The bank modules Bank0 and Bank1 share the readout module R01, and the bank modules Bank2 and Bank3 share the readout module R23. In other words, every two of the bank modules share a single one of the readout modules. Data processing in the column memory circuit is roughly as described below. Gray code data GC from an analog-to-digital converter (ADC) 120 (not shown in FIG. 2; see FIG. 1 for details) and comparator data CMP from a timing control circuit (not shown in FIG. 2) are input as external data to the bank modules Bank0, Bank1, Bank2 and Bank3. The bank modules Bank0 and Bank1 provide the data that they have processed to the associated readout module R01 and then to the data transmission module 170, and the bank modules Bank2 and Bank3 provide the data that they have processed to the associated readout module R23 and then to the data transmission module 170 via the readout module R01. The readout modules R01 and R23 together provide shifted readout, and the data transmission module 170 receives the data that has been processed in the readout modules R01 and R23 and outputs it from the column memory circuit 130.

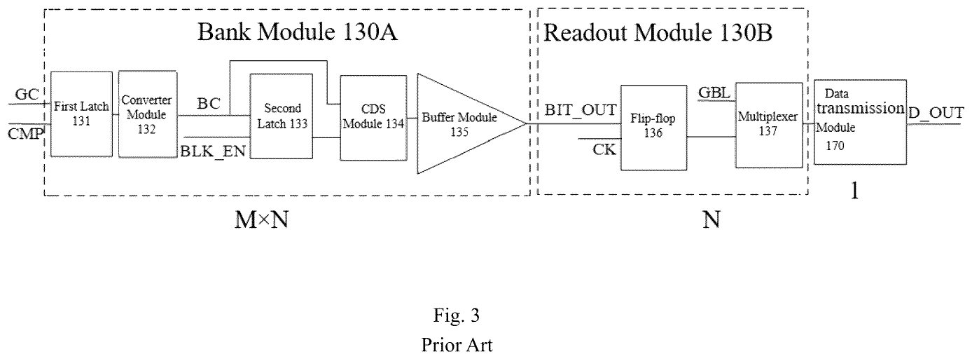

FIG. 3 schematically illustrates the topology of a column memory circuit in a conventional ISP. As shown in FIG. 3, in this example, the column memory circuit 130 includes M×N bank modules (in FIG. 3, only an i-th bank module 130A is schematically shown; 1≤i≤(M×N)), N readout modules (in FIG. 3, only a j-th readout module 130B is schematically shown; 1≤j≤N) and a data transmission module 170. Associated data processing is roughly as described below. Gray code data GC is latched in a first latch 131 at a falling edge of a signal of comparator data CMP, and a transcoder module 132 then converts the latched Gray code data GC into binary data BC. A second latch 133 latches a black-level signal BLK_EN from an image sensor and cooperates with a correlated double sampling (CDS) module 134 to provide CDS processing. A buffer module 135 transmits a data signal BIT_OUT that has experienced CDS processing from the bank module 130A to the associated readout module 130B. Similarly, the N readout modules together serve as a shift register. Further, the readout module 130A first sends data from the bank module 130A and a bank module sharing the readout module 130A with the bank module 130A (not shown in FIG. 3; e.g., like the bank modules Bank0 and Bank1 that share the readout module R01 in FIG. 2) through a flip-flop 136 (e.g., a D-type flip-flop (DFF)) and a multiplexer 137. Immediately after that, the multiplexer 137 is switched to an output signal terminal GBL of an adjacent readout module. The readout module 130B outputs data from other bank modules through the multiplexer 137 (e.g., like the case shown in FIG. 2, in which data from the bank modules Bank2 and Bank3 that share the readout module R23 is passed to the readout module R23 and then to the readout module R01) and then from the column memory circuit 130 through the data transmission module 170.

It should be noted that only aspects of the column memory circuits that are relevant to the present invention are described herein, and reference is made to related techniques known to those skilled in the art for more details of other aspects not mentioned therein to get a better understanding.

As can be seen from FIG. 3, conventional column memory circuits usually include a data transmission module 170, N readout modules 130B and M×N bank modules 130A (both M and N depend on the resolution of the image sensor). Most functions are performed by the bank modules 130A. The inventors have conducted extensive research and thereby found that circuits with complex functions, such transcoder modules 132 and CDS modules 134, are typically composed of a large number of transistors. Such complex functions, coupled with a great number of bank modules 130A, often make the column memory circuits 130 have a large footprint and barely suitable for use in low-cost image sensor products.

Based on these findings, it is a principal object of the present invention to provide a column memory circuit, image sensor and imaging device. According to the present invention, the column memory circuit has a significantly reduced area and good performance and can significantly reduce the cost of an image sensor employing it.

It should be noted that the proposed column memory circuit and chip can be used in the proposed image sensor and imaging device. Additionally, the proposed image sensor can be used in the proposed imaging device. It will be understood that, as used herein, the terms “imaging device” or the like encompass general imaging devices, including but not limited to, cameras, video cameras, mobile phones, tablet computers, learning assistants, and medical imaging devices equipped with an image sensor, for example.

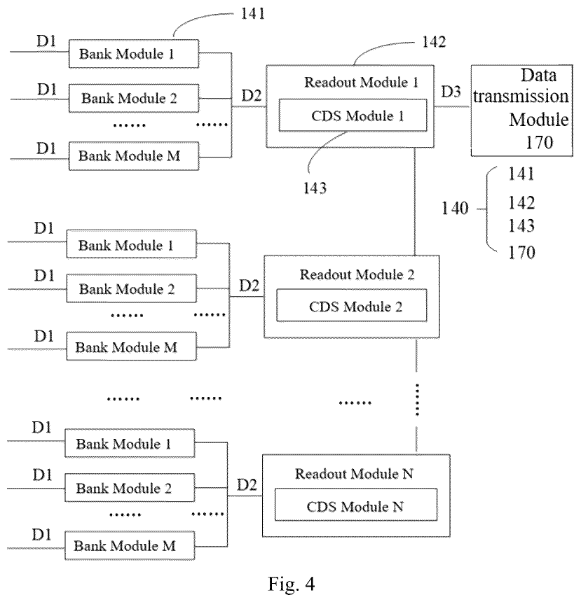

To this end, the present invention provides a column memory circuit. For example, reference is made to FIG. 4, a schematic block diagram of a column memory circuit embodying the present invention. As shown in FIG. 4, a column memory circuit 140 according to the present invention includes M×N bank modules 141, N readout modules 142 and a data transmission module 170. In this column memory circuit 140, CDS modules 143 are arranged in the readout module 142. A first terminal of each bank module 141 is configured to receive a first data signal D1, and a second terminal thereof is coupled to a first terminal of an associated one of the readout modules 142, with a second terminal of the readout module 142 being coupled to the data transmission module 170, where M≥2. Additionally, the bank modules 141 are configured to convert the received first data signals D1 into second data signals D2, and the readout modules 142 are configured for CDS processing of the second data signals D2 by the CDS modules 143, producing a third data signal D3. The data transmission module 170 is configured to output the third data signal D3.

Thus, differing from conventional designs with CDS modules being incorporated in bank modules, the column memory circuit of the present invention incorporates the CDS modules 143 in the readout modules 142. This design leverages the fact that the number of readout modules 142 is much less than that of bank modules 141 to significantly reduce the number of CDS modules 143, resulting in cost savings and reducing the circuit area that they occupy. Accordingly, the footprint of the column memory circuit can be significantly reduced while ensuring its good performance. The cost of an image sensor employing this proposed column memory circuit can be significantly reduced, and the column memory circuit can be suitably used in low-cost image sensors.

In particular, compared with conventional designs with CDS modules being incorporated in bank modules, the present invention saves (M−1)×N CDS modules 143 through incorporating the CDS modules 143 in the readout modules 142.

Preferably, in some exemplary embodiments, each CDS module 143 includes a plurality of first transistors (not shown in FIG. 4). This design with each CDS module 143 being constructed of a plurality of first transistors provides ease of implementation and is advantageous in easy availability of the transistors at a low price. It should be noted and understood by those skilled in the art that although the CDS modules 143 have been described above as being implemented by the first transistors, this merely represents a preferred illustrative embodiment and is not intended to limit the invention in any sense. The present invention is not limited to any particular implementation of the CDS modules 143, and reference is made to related techniques known to those skilled in the art for more details of the CDS modules 143, and further detailed description thereof is omitted herein for the sake of brevity.

For example, if each CDS module 143 includes P first transistors, totally M×N×P first transistors would be required in the conventional case of arranging the CDS modules in the bank modules. In contrast, only N×P first transistors are required in the proposed column memory circuit. Therefore, the present invention saves (M−1)×N×P transistors, compared with the prior art.

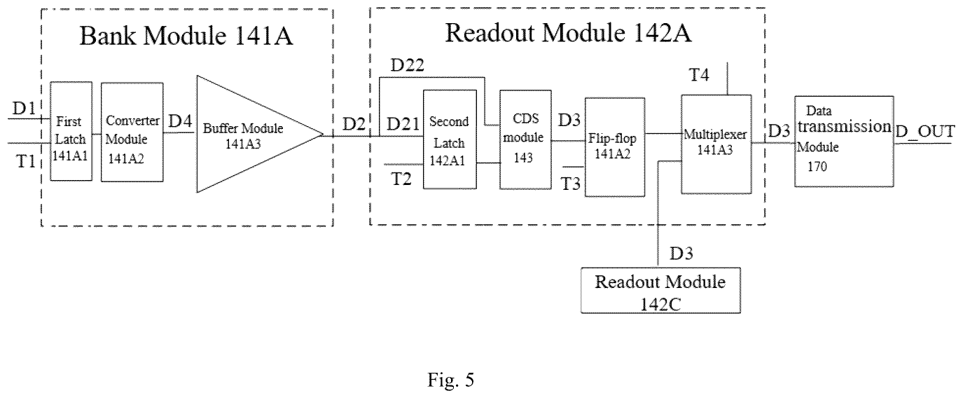

For example, reference is made to FIG. 5, which schematically illustrates the topology of a column memory circuit according to a first embodiment of the present invention, in which only an i-th bank module 141A and a j-th readout module 142A are shown as an example. As shown in FIG. 5, in the column memory circuit according to the first embodiment of the present invention, each bank module 141A includes a first latch 141A1, a transcoder module 141A2 and a buffer module 141A3, which are connected in sequence. Each readout module 142A further includes a second latch 142A1, a flip-flop 142A2 and a multiplexer 142A3, and the second latch 142A1, the CDS module 143, the flip-flop 142A2 and the multiplexer 142A3 are connected in sequence. The first latch 141A1 is configured to, when receiving a first control signal T1 (e.g., in the form of comparator data CMP) from an image sensor, latch the first data signal D1 (e.g., a voltage signal in a Gray code format, which represents the value of a pixel output voltage) and provide the latched first data signal D1 to the transcoder module 141A2. The transcoder module 141A2 is configured to transcode the first data signal D1 into a fourth data signal D4 (e.g., a binary voltage signal). The buffer module 135 is configured to buffer the fourth data signal D4, obtaining a first set of second data signals D21 (binary voltage signals representing voltage values of a black-level signal) for transmission to the second latch. After the first set of second data signals D21 is obtained, the buffer module 135 buffers a second set of second data signals D22 (binary voltage signals representing pixel voltage values) for transmission to the CDS module 143. The second latch 142A1 is configured to, when receiving a second control signal T2 (e.g., a stored black-level signal), latch the first set of second data signals D21, and the CDS module 143 is configured to perform CDS processing on the first set of second data signals D21 and the second set of second data signals D22, producing a third data signal D3 (a binary voltage signal). The flip-flop 142A2, when receiving a third control signal T3 from the image sensor (e.g., a readout clock signal), passes the third data signal D3 on to the multiplexer 142A3. The multiplexer 142A3 is configured to select one of such third data signals D3 based on a fourth control signal T4 from the image sensor (e.g., a bank module select signal) and provide it to the data transmission module 170.

In the column memory circuit according to the first embodiment of the present invention, each bank module 141A includes a first latch 141A1, a transcoder module 141A2 and a buffer module 141A3. The first latch 141A1 ensures stability of the first data signal D1, and the transcoder module 141A2 converts the first data signal D1 into the fourth data signal D4, laying a solid foundation for efficient data signal processing of the readout module 142A. Through buffering the fourth data signal D4 in the buffer module 141A3, it is ensured that such fourth data signals D4 are robustly transferred from a plurality of bank modules coupled to the readout module 142A to the second latch 142A2. Additionally, in the column memory circuit, each readout module 142A includes a second latch 142A1, a CDS module 143, a flip-flop 142A2 and a multiplexer 142A3, which are connected in sequence. The second latch 142A1 lays a solid foundation for suppression of fixed-pattern noise and reset noise in the second data signals D2 by the CDS module 143 and hence for improved image quality. Under the control of the fourth control signal T4, the flip-flop 142A2 can well coordinate and synchronize switching of the multiplexer 142A3 between readout modules 142 with the readout timing, thereby allowing the multiplexer 142A3 to select and output the third data signal D3 from an appropriate one of the readout modules 142 (for example, the multiplexer 142A3 is able to selectively output the third signal data D3 from the readout module 142A or the third signal data D3 from another readout module 142C).

Preferably, still in the context of the readout module 142A as an example, an input terminal of the multiplexer 142A3 is coupled to an output terminal of the flip-flop 142A2 in the readout module 142A, and another input terminal of the multiplexer 142A3 is coupled to the output terminal of the multiplexer (not shown in FIG. 5) in another readout module 142C that is adjacent to the readout module 142A. Further, most of the readout modules 142 are coupled to the data transmission module 170 via the multiplexers in the other readout modules 142, which are adjacent to those readout modules 142 and have the output terminals of their multiplexers directly coupled to the data transmission module 170.

For example, in some exemplary embodiments, the first data signal D1 is encoded using Gray code, and the fourth data signal D4 is binary encoded. Encoding the first data signal D1 in a Gray code format can effectively reduce transmission errors, and the binary encoded fourth data signal D4 facilitates efficient subsequent processing in the readout module. It should be noted and understood by those skilled in the art that the present invention is not limited to any particular format of the first data signal D1 or the fourth data signal D4. In practical implementations of the present invention, any appropriate format may be employed, as required.

For example, in some exemplary embodiments, the flip-flop 142A2 includes a D-type flip-flop. In the column memory circuit of the present invention, designing the flip-flop 142A2 in the readout module 142A as a D-type flip-flop ensures desirable serial transmission of the third data signal D3.

As can be seen from the above description, in the column memory circuit of the invention, since the CDS module 134 is arranged in the readout module 142A, more data is output from the bank module 141A. Although performance of the column memory circuit could be further improved by selecting the buffer module 141A3 as one with higher performance, it is still considered overall cost-effective.

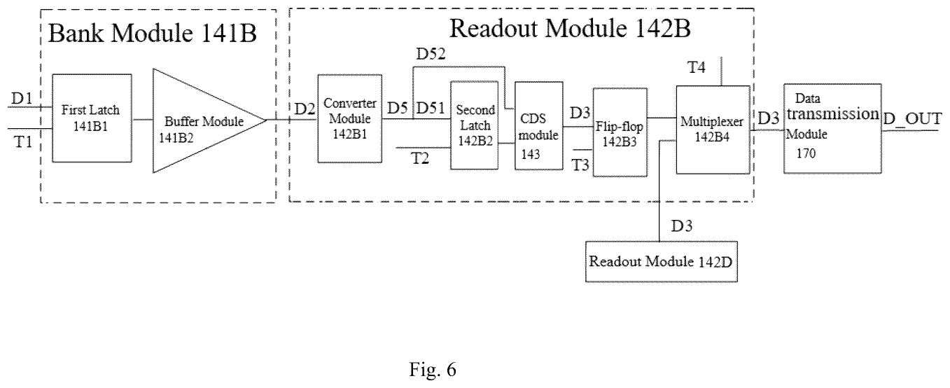

For example, reference is made to FIG. 6, which schematically illustrates the topology of a column memory circuit according to a second embodiment of the present invention. Similar to the column memory circuit of the first embodiment shown in FIG. 5, only an i-th bank module 141B and a j-th readout module 142B are shown, as an example, in FIG. 6. As can be seen from a comparison made between FIGS. 5 and 6, the column memory circuit of the second embodiment is substantially based on the same principles as the column memory circuit of the first embodiment. For brevity, all features common to these embodiments are not repeated herein, and only features unique to the second embodiment are described below. Reference is made to the foregoing description in connection with the first embodiment for more details of such common features that are not mentioned hereinafter.

As shown in FIG. 6, in the column memory circuit according to the second embodiment of the present invention, each bank module 141B includes a first latch 141B1 and a buffer module 141B2, which are connected in sequence. Each readout module 142B further includes a transcoder module 142B1, a second latch 142B2, a flip-flop 142B3 and a multiplexer 142B4, and the transcoder module 142B1, the second latch 142B2, the CDS module 143, the flip-flop 142B3 and the multiplexer 142B4 are connected in sequence. The first latch 141B1 is configured to, when receiving a first control signal T1 (e.g., in the form of comparator data CMP) from an image sensor, latch the first data signal D1 (e.g., as a voltage signal in a Gray code format, which represents a pixel output voltage) and provide the latched first data signal D1 to the transcoder module 141B2. The buffer module 141B2 is configured to buffer the first data signal D1, obtaining second data signals D2 (e.g., voltage signals in a Gray code format, which represent pixel output voltages), and provide the second data signals D2 to the transcoder module 142B1. The transcoder module 142B1 is configured to transcode the second data signals D2 into a first set of fifth data signals D51 (e.g., binary voltage signals representing voltage values of a black-level signal) for transmission to the second latch. After the first set of fifth data signals D51 is produced, the transcoder module 142B1 transcodes subsequently received second data signals D2 into a second set of fifth data signals D52 (binary voltage signals representing pixel voltage values) for transmission to the CDS module 143. The second latch 142B2 is configured to, when receiving a second control signal T2 (e.g., a stored black-level signal), latch the first set of fifth data signals D51, and the CDS module 143 is configured to perform CDS processing on the first set of fifth data signals D51 and the second set of fifth data signals D52, producing a third data signal D3. The flip-flop 142B3, when receiving a third control signal T3 from the image sensor (e.g., a readout clock signal), passes the third data signal D3 on to the multiplexer 142B4. The multiplexer 142B4 is configured to select one of such third data signals D3 based on a fourth control signal T4 from the image sensor (e.g., a bank module select signal) and provide it to the data transmission module 170.

In the column memory circuit according to the second embodiment of the present invention, each bank module 141B includes a first latch 141B1 and a buffer module 141B2. The first latch 141B1 ensures stability of the first data signal D1. Through buffering the first data signal D1 in the buffer module 141B2, it is ensured that such second data signals D2 are robustly transferred from a plurality of bank modules coupled to the readout module 142B to the transcoder module 142B1. Additionally, in the column memory circuit, each readout module 142B includes a transcoder module 142B1, a second latch 142B2, a CDS module 143, a flip-flop 142B3 and a multiplexer 142B4, which are connected in sequence. The transcoder module 142B1 converts the second data signals D2 into the fifth data signals D5, laying a solid foundation for efficient data signal processing of the second latch 142B2. The second latch 142B4 lays a solid foundation for suppression of fixed-pattern noise and reset noise in the fifth data signals D5 by the CDS module 143 and hence for improved image quality. The flip-flop 142B3 can synchronize switching of the multiplexer 142B4 between readout modules 142 with the readout timing, thereby allowing the multiplexer 142B4 to select and output the third data signal D3 from an appropriate one of the readout modules 142 (for example, the multiplexer 142B4 is able to selectively output the third signal data D3 from the readout module 142B or the third signal data D3 from another readout module 142D).

Preferably, in some exemplary embodiments, the transcoder module 142B1 includes a plurality of second transistors (not shown in FIG. 6). This design with the transcoder module 142B1 being constructed of a plurality of second transistors is advantageous in simple logic and ease of implementation. It should be noted and understood by those skilled in the art that although the transcoder module 142B1 has been described above as being implemented by the second transistors, this merely represents a preferred illustrative embodiment and is not intended to limit the invention in any sense. The present invention is not limited to any particular implementation of the transcoder module 142B1, and reference is made to related techniques known to those skilled in the art for more details of the transcoder module 142B1, and further detailed description thereof is omitted herein for the sake of brevity.

For example, if each CDS module includes P first transistors and each transcoder module includes Q second transistors, totally M×N×P first transistors and M×N×Q second transistors would be required in the conventional case of arranging both the converter and CDS modules in the bank modules. In contrast, only N×P first transistor and N×Q second transistors are required by the two types of modules in the column memory circuit according to the second embodiment of the present invention. Therefore, the present invention can save (M−1)×N×(P+Q) transistors, compared with the prior art.

As can be seen from the above description, in the column memory circuit according to the second embodiment of the present invention, since the transcoder module 142B1 and the CDS module 143 are both arranged in the readout module 142B, more data is output from the bank module 141B. Although performance of the column memory circuit could be further improved by selecting the buffer module 141B2 as one with higher performance and supporting a greater bit-width of data, it is still considered overall cost-effective.

It should be noted and understood by those skilled in the art that the present invention is not limited to any particular type of image sensor. As a non-limiting example, the image sensor may be a CMOS image sensor. Additionally, the present invention is not limited to any particular value of M, N, P or Q. Preferably, the values of M and N are dependent on the resolution of the image sensor. In practical implementations of the present invention, the values may be appropriately determined, as required.

In a third embodiment of the present invention, there is provided a chip of an image sensor, on which a column memory circuit as defined in any of the foregoing embodiments is integrated. Through integrating the column memory circuit of the invention onto the chip, not only the cost of the image sensor can be reduced, its degree of integration can also be increased.

In a fourth embodiment of the present invention, there is provided an image sensor including a column memory circuit or chip as defined in any of the foregoing embodiments. Since the image sensor is based on the same inventive concept as the column memory circuit, it provides at least all the advantages of the column memory circuit. Such advantages have been described in detail above in connection with the column memory circuit embodiments and are not repeated herein, and reference is made to the above description for more details.

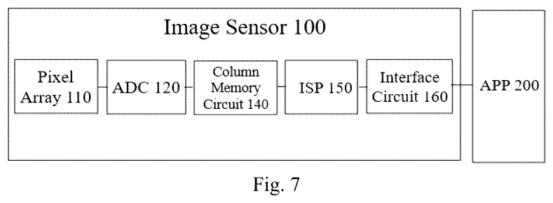

In a fifth embodiment of the present invention, there is provided an imaging device including a column memory circuit, chip or image sensor as defined in any of the foregoing embodiments. For example, reference is made to FIG. 7, a schematic block diagram of the imaging device according to the fifth embodiment. As shown in FIG. 7, an image sensor 100 in the imaging device includes a column memory circuit 140 as defined in any of the foregoing embodiments. Since the imaging device is based on the same inventive concept as the image sensor, which is in turn based on the same inventive concept as the column memory circuit, it provides at least all the advantages of the column memory circuit. Such advantages have been described in detail above in connection with the column memory circuit embodiments and are not repeated herein, and reference is made to the above description for more details.

In addition, as shown in FIG. 7, the imaging device further includes an application (APP) 200, and the image sensor 100 further includes a pixel array 110, an ADC 120, an ISP 150 and an interface circuit 160. For more details of the ISP 150 and the application 200 in the imaging device, reference is made to related techniques known to those skilled in the art, and further description thereof is omitted herein for the sake of brevity. It will be understood that, as noted above, the present invention is not limited to any particular type of imaging device. Examples of the imaging device may include, but are not limited to, video cameras, still camera and mobile phones with a camera function.

Compared to the prior art, the column memory circuit, chip, image sensor and imaging device of the present invention offer the following advantages:

Differing from conventional designs with CDS modules being incorporated in bank modules, the column memory circuit of the present invention incorporates CDS modules in readout modules. This design leverages the fact that the number of readout modules is much less than that of bank modules to significantly reduce the number of CDS modules, resulting in cost savings and reducing the circuit area that they occupy. Accordingly, the footprint of the column memory circuit can be significantly reduced while ensuring its good performance. The cost of an image sensor employing this column memory circuit can be significantly reduced, and the column memory circuit can be suitably used in low-cost image sensors.

Further, the various functional modules in the embodiments disclosed herein may be integrated into a discrete component, or provided as separate modules. Alternatively, two or more such modules may be integrated into a discrete component.

The description presented above is merely that of a few preferred embodiments of the proposed column memory circuit, chip, image sensor and imaging device and is not intended to limit the scope thereof in any sense. Any and all changes and modifications made by those of ordinary skill in the art in light of the above teachings fall within the scope as defined in the appended claims. Apparently, those skilled in the art can make various modifications and variations to the present invention without departing from the spirit and scope thereof. Accordingly, the invention is intended to embrace all such modifications and variations if they fall within the scope of the appended claims and equivalents thereof.

What is claimed is:

1. A column memory circuit for use in an image sensor, the column memory circuit comprising M×N bank modules, N readout modules and a data transmission module, the column memory circuit further comprising correlated double sampling modules arranged in the respective readout modules, each bank module having a first terminal configured to receive a first data signal, each bank module having a second terminal coupled to a first terminal of an associated one of the readout modules, each readout module having a second terminal coupled to the data transmission module, M≥2,
the bank modules configured to convert the received first data signals into second data signals, the readout modules configured to perform correlated double sampling processing on the second data signals by the correlated double sampling modules, which produces a third data signal, the data transmission module configured to output the third data signal.

2. The column memory circuit according to claim 1, wherein each correlated double sampling module comprises a plurality of first transistors.

3. The column memory circuit according to claim 1, wherein each bank module comprises a first latch, a transcoder module and a buffer module, which are connected in sequence, wherein the associated readout module further comprises a second latch, a flip-flop and a multiplexer, and the second latch, the respective correlated double sampling module, the flip-flop and the multiplexer are connected in sequence,
the first latch configured to, when receiving a first control signal from the image sensor, latch the first data signal and provide the latched first data signal to the transcoder module, the transcoder module configured to transcode the first data signal to obtain a fourth data signal, the buffer module configured to buffer the fourth data signal to obtain a first set of second data signals for transmission to the second latch and, after the first set of second data signals is obtained, buffer a second set of second data signals for transmission to the correlated double sampling module,
the second latch configured to, when receiving a second control signal, latch the first set of second data signals, the correlated double sampling module configured to perform correlated double sampling processing on the first set of second data signals and the second set of second data signals to obtain third data signals, the flip-flop configured to send the third data signals to the multiplexer when receiving a third control signal from the image sensor, the multiplexer configured to select one of the third data signals to send to the data transmission module based on a fourth control signal from the image sensor.

4. The column memory circuit according to claim 3, wherein the first data signal is encoded using Gray code, and the fourth data signal is binary encoded.

5. The column memory circuit according to claim 3, wherein the flip-flop includes a D-type flip-flop.

6. The column memory circuit according to claim 1, wherein each bank module comprises a first latch and a buffer module, which are connected in sequence, wherein the associated readout module further comprises a transcoder module, a second latch, a flip-flop and a multiplexer, and the transcoder module, the second latch, the respective correlated double sampling module, the flip-flop and the multiplexer are connected in sequence,
the first latch configured to, when receiving a first control signal from the image sensor, latch the first data signal and provide the latched first data signal to the buffer module, the buffer module configured to buffer the first data signal and thereby obtain second data signals and provide the second data signals to the transcoder module,
the transcoder module configured to transcode the second data signals into a first set of fifth data signals for transmission to the second latch and, after the first set of fifth data signals is obtained, transcode subsequently received second data signals into a second set of fifth data signals for transmission to the correlated double sampling module, the second latch configured to, when receiving a second control signal, latch the first set of fifth data signals, the correlated double sampling module configured to perform correlated double sampling processing on the first and second sets of fifth data signals, producing third data signals, the flip-flop, when receiving a third control signal from the image sensor, passing the third data signals on to the multiplexer, the multiplexer configured to select one of the third data signals according to a fourth control signal from the image sensor and provide it to the data transmission module.

7. The column memory circuit according to claim 6, wherein the transcoder module comprises a plurality of second transistors.

8. A chip for use in an image sensor, wherein the chip is integrated with the column memory circuit according to claim 1.

9. An image sensor, comprising
a column memory circuit for use in an image sensor, the column memory circuit comprising M×N bank modules, N readout modules and a data transmission module, the column memory circuit further comprising correlated double sampling modules arranged in the respective readout modules, each bank module having a first terminal configured to receive a first data signal, each bank module having a second terminal coupled to a first terminal of an associated one of the readout modules, each readout module having a second terminal coupled to the data transmission module, M≥2, the bank modules configured to convert the received first data signals into second data signals, the readout modules configured to perform correlated double sampling processing on the second data signals by the correlated double sampling modules, which produces a third data signal, the data transmission module configured to output the third data signal; or
the chip according to claim 8.
